(19) United States
(12) Patent Application Publication
(10) Pub. No.: US 2025/0393381 A1
(43) Pub. Date: Dec. 25, 2025

(54) DISPLAY DEVICE COMPRISING COMPOSITE FILLER

(71) Applicant: LG ELECTRONICS INC., Seoul (KR)

(72) Inventors: Naree KIM, Seoul (KR); Dongkyu LEE, Seoul (KR); Eunjung HWANG, Seoul (KR); Hongkey PARK, Seoul (KR)

(73) Assignee: LG ELECTRONICS INC., Seoul (KR)

(21) Appl. No.: 18/880,405

(22) PCT Filed: Jul. 11, 2022
(86) PCT No.: PCT/KR2022/010032

§ 371 Date: Dec. 31, 2024

(51) Int. Cl. H10H 29/80; H01L 25/075; H10H 29/85; H10H 29/853; H10H 29/855

(52) U.S. Cl. CPC H10H 29/882; H01L 25/0753; H10H 29/853; H10H 29/855; H10H 29/857

(57) ABSTRACT

The present disclosure is applicable to the technical field of display devices and relates to a display device using, for example, a light emitting diode (LED). To this end, the present disclosure may comprise: a wiring board; an electrode pad partitioned on the wiring board; a plurality of light emitting diodes connected to the electrode pad to form unit pixels; an encapsulation layer formed on the wiring board to cover the plurality of light emitting diodes; an optical film positioned on the encapsulation layer; and a light scattering agent dispersed and distributed within the encapsulation layer, wherein the light scattering agent may comprise: a first light scattering agent; and a second light scattering agent having a scattering degree different from that of the first light scattering agent.

### TECHNICAL FIELD

The present disclosure is applicable to the technical field related to display devices, and relates to, for example, a display device using a Light Emitting Diode (LED).

### BACKGROUND ART

With the development of the information society, the demand for display devices is also increasing in various forms, and in recent years, various display devices such as Liquid Crystal Display Device (LCD), Plasma Display Panel (PDP), Electro Luminescent Display (ELD), Vacuum Fluorescent Display (VFD), Organic Light Emitting Diode (OLED), and Micro Light Emitting Diode (Micro Light Emitting Diode), and the like have been studied and used.

Digital Signage is a display device that provides specific information as well as broadcast programs in public places such as airports, hotels, hospitals, subway stations, and the like as a communication tool that can induce marketing, advertising, training effects, and customer experience of companies as well as general TVs.

Digital signage is a medium that displays various contents and commercial advertisements by installing a display panel such as Liquid Crystal Display (LCD), Plasma Display Panel (PDP), Organic Light Emitting Diode (OLED), Micro LED (Light Emitting Diode), and the like in certain outdoor places or devices such as street furniture, and the like, and may be installed in public movements such as apartment elevators, subway stations, buses, universities, banks, convenience stores, discount stores, and shopping malls.

Recently, as digital signage has become large and super-large, many studies have been conducted to improve the image quality of display panels.

Such digital signage is implemented as a modular display device in which several display modules are combined. Such a module display may use a Light Emitting Device (LED) as a pixel.

However, after forming a pixel with an LED, the color of each module may look different depending on a viewing angle due to the structural tilt of the LED and the difference in orientation angle between chips.

Therefore, the demand for solutions of these problems rises.

### DISCLOSURE

### Technical Tasks

According to an embodiment of the present disclosure, one technical task of the present disclosure is to provide a display device including a composite filler capable of improving a refractive index by increasing a light scattering degree of the display device.

In addition, another technical task of the present disclosure is to provide a display device including a composite filler that can exert a large scattering effect even if a small amount is added using a composite filler (light scattering agent).

In addition, further technical of the present disclosure is to provide a display device including a composite filler that can change a refractive index through changes according to a combination of various types of scattering agents and reduce the overall content of the scattering agent.

### Technical Solutions

In one technical aspect of the present disclosure, provided is a display device including a wiring substrate, an electrode pad partitioned on the wiring substrate, a plurality of light emitting devices connected to the electrode pad to form a unit pixel, an encapsulation layer formed on the wiring substrate to cover a plurality of the light emitting devices, an optical film disposed on the encapsulation layer, and a light scattering agent dispersed and distributed in the encapsulation layer, wherein the light scattering agent may include a first light scattering agent and a second light scattering agent having a scattering degree different from a scattering degree of the first light scattering agent.

The light scattering agent may include at least one of Zr, Si, Ti, Zn, BaS, and oxides thereof.

The encapsulation layer may include a first layer covering the plurality of the light emitting devices and a second layer on the first layer.

The second light scattering agent may be included in the second layer.

The scattering degree of the first light scattering agent may be greater than the scattering degree of the second light scattering agent.

The encapsulation layer may further include a third layer disposed on side surfaces of the plurality of the light emitting devices.

A third light scattering agent having a scattering degree different from the scattering degree of the first light scattering agent and the second light scattering agent may be included in the third layer.

A scattering degree of the third light scattering agent may be higher than the scattering degree of the first light scattering agent and the second light scattering agent.

A height of the third layer may be equal to or less than a height of the light emitting device.

The display device may further include a side optical layer disposed on a side surface of the encapsulation layer.

A fourth light scattering agent having a scattering degree different from the scattering degree of the first light scattering agent and the second light scattering agent may be included in the side optical layer.

A diameter or size of the light scattering agent may be 10 nm to 10 μm.

In another technical aspect of the present disclosure, provided is a display device including a wiring substrate, an electrode pad partitioned on the wiring substrate, a plurality of light emitting devices connected to the electrode pad to form a unit pixel, an encapsulation layer formed on the wiring substrate to cover a plurality of the light emitting devices, an optical film disposed on the encapsulation layer, and a filler dispersed and distributed in the encapsulation layer, wherein the filler may include a first filler including Zr oxide and a second filler including Si oxide.

The encapsulation layer may include a first layer covering the plurality of the light emitting devices and a second layer on the first layer.

The second filler may be included in the second layer.

The encapsulation layer may further include a third layer disposed on side surfaces of the plurality of the light emitting devices.

A third filler having optical characteristics different from optical characteristics of the first filler and the second filler may be included in the third layer.

The third filler may include Ti oxide.

A degree of scattering light of the third filler may be higher than a degree of scattering light of the first filler and the second filler.

The display device may further include a side optical layer disposed on a side surface of the encapsulation layer, and a fourth scattering agent having a scattering degree different from a scattering degree of the first light scattering agent or the second light scattering agent may be included in the side optical layer.

### ADVANTAGEOUS EFFECTS

According to an exemplary embodiment of the present disclosure, the following effects are obtained.

First, a light scattering agent is a material having a relatively large refractive index and has an effect of improving a refractive index. The light scattering agent having such a large refractive index may exhibit a large scattering effect even when a small amount is added.

For example, a light scattering agent having a small size may have stability for a dispensing process. In addition, it may have the advantage of less sedimentation after a curing process through the dispensing process.

In addition, when two or more types of light scattering agents are mixed in the same layer, both types of scattering agents may exert the effect of light scattering or one light scattering agent may be used to prevent the sedimentation of the other major light scattering agent.

In addition, when two or more light scattering agents are used together, it is possible to change a refractive index through changes according to a combination of various types of scattering agents, and the overall content of the scattering agent may be reduced.

### DESCRIPTION OF DRAWINGS

FIG. 1 is a schematic cross-sectional diagram illustrating a display device according to a first embodiment of the present disclosure.

FIG. 2 is a schematic cross-sectional diagram illustrating a display device according to a second embodiment of the present disclosure.

FIG. 3 is a graph illustrating characteristics of a light scattering agent used in a display device according to an embodiment of the present disclosure.

FIG. 4 is a graph illustrating a change in luminance according to a viewing angle of a display device in a state where a light scattering agent is not applied as a comparative example.

FIG. 5 is a graph illustrating a change in luminance for each viewing angle of a display device according to an embodiment of the present disclosure.

FIG. 6 is a schematic cross-sectional diagram illustrating a display device according to a third embodiment of the present disclosure.

FIG. 7 is a schematic cross-sectional diagram illustrating a display device according to a fourth embodiment of the present disclosure.

FIG. 8 is an enlarged diagram illustrating a side optical layer of the display device according to the fourth embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described in this specification encompasses all display devices that present information through unit pixels or a set of unit pixels. Therefore, it is not limited to finished products and can also apply to components. For example, a panel, which is a component of a digital TV, independently qualifies as a display device as described in this specification. Finished products may include devices such as mobile phones, smartphones, laptop computers, digital broadcasting terminals, PDAs (personal digital assistants), PMPs (portable multimedia players), navigation systems, Slate PCs, Tablet PCs, Ultra Books, digital TVs, and desktop computers.

However, it should be readily apparent to those skilled in the art that the configurations according to the embodiments described in this specification may also be applicable to newly developed forms of products in the future, as long as they are capable of displaying content.

Furthermore, the semiconductor light-emitting devices mentioned in this specification include concepts such as LEDs, mini LEDs, and micro LEDs, which can be used interchangeably.

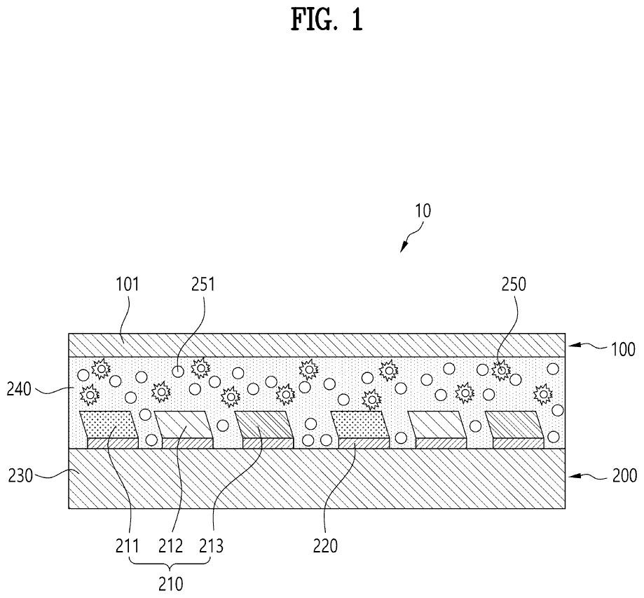

FIG. 1 is a schematic cross-sectional diagram illustrating a display device according to a first embodiment of the present disclosure.

As shown in FIG. 1, a display panel 200 may implement an image by a unit pixel 210 (211, 212, and 213) arranged on a substrate 230. An encapsulation layer 240 may be formed on the unit pixels 210 (211, 212, and 213).

The unit pixel 210 (211, 212, and 213) may include light emitting devices 211, 212, and 213. For example, the unit pixel 210 may include a red light emitting device 211, a green light emitting device 212, and a blue light emitting device 213.

The red light emitting device 211, the green light emitting device 212, and the blue light emitting device 213 constituting the unit pixel 210 may be electrically connected to an electrode pad 220 arranged on the substrate 230.

Meanwhile, unlike the illustration, the unit pixel 210 may include a stacked light emitting device (LED) in which red, green, and blue are formed in a single chip structure.

A composite optical film 100 may be positioned on the display panel 200. In this way, the composite optical film 100 may be attached onto the display panel 200. The display panel 200 to which the composite optical film 100 is attached may be referred to as a display device 10.

Although not shown separately, a modular display device may be implemented in a manner that a plurality of the display devices 10 are coupled to implement a larger display area. For example, the display device 10 may be a single display module constituting a modular display device. As such, a plurality of display devices 10 may be coupled in parallel to form a modular display device. A detailed description thereof will be omitted.

Here, the optical film 100 may include a black dye layer 101 attached to the display panel 200. Although not shown separately, the optical film 100 may include a parent body. Such a parent body may include an adhesive layer and a transparent protective layer. In addition, a separate optical film may be further provided.

The encapsulation layer 240 may be disposed on the substrate 230 provided with the electrode pad 220. The encapsulation layer 240 is made of an insulating and flexible material such as polyimide (PI), PET, and PEN, and the like, and may be integrally formed with the substrate 230 to form a single substrate. As described above, the substrate 230 including the electrode pad 220 may be a wiring substrate in which a wiring electrode (not shown) is connected to the electrode pad 220. Hereinafter, the substrate 230 will be described as the wiring substrate 230 for example, and the substrate and the wiring substrate are described by using the same reference number.

A Filler 250 and 251 may be included in the encapsulation layer 240. The filler 250 and 251 may include a first filler 250 and a second filler 251 having different optical characteristics, respectively.

Here, the optical characteristic may be a characteristic of refracting or scattering light emitted from the light emitting device 210.

Light emitted from the light emitting devices 211, 212, and 213 may be refracted or scattered by the filler 250 and 251. Light scattered by the filler 250 and 251 may be emitted to the outside of the encapsulation layer 240.

After curing, the encapsulation layer 240 may have light transmittance. For example, the cured encapsulation layer 240 including silicon may have a refractive index of 1.4 to 1.6. Accordingly, light may be totally reflected in the encapsulation layer 240. The filler 250 and 251 may refract or scatter light that is totally reflected in the encapsulation layer 240.

That is, the filler 250 and 251 may serve as a light scattering agent. Therefore, the filler 250 and 251 may be referred to as a light scattering agent. In the following description, the filler and the light scattering agent may refer to the same entity.

The filler 250 and 251 may include at least one of Zr, Si, Ti, Zn, BaS, and oxides thereof. For example, the filler 250 and 251 may be spherical or amorphous. For example, the first filler 250 may be amorphous and the second filler 251 may be spherical.

Also, a diameter or size of the filler 250 and 251 may be 10 nanometers (nm) to 10 micrometers (μm). The content (weight ratio) of the filler 250 and 251 may be 0.01% to 30% with respect to the encapsulation layer 240.

For example, the first filler 250 may include Zr oxide. Also, for example, the second filler 251 may include Si oxide.

In this case, the optical characteristics of the first filler 250 may be different from the optical characteristics of the second filler 251. As mentioned above, the optical characteristics may be the characteristics of refracting or scattering light emitted from the light emitting device 210.

In addition, a characteristic of refracting or scattering light emitted from the light emitting device 210 may be expressed as a scattering degree.

In this way, the encapsulation layer 240 may include light a scattering agent 250 and 251, and the light scattering agent 250 and 251 may include a first light scattering agent 250 and a second light scattering agent 251 having a different scattering degree from the first light scattering agent 250.

Such a scattering degree may be confirmed by measuring the intensity of light of scattered light generated after irradiating the excitation light. In this case, blue light (for example, a wavelength of 435 nm or 450 nm) may be used as the excitation light.

Meanwhile, the scattering degree may be defined as the degree to which light emitted from the light emitting devices 211, 212, and 213 is scattered relative to a unit mass.

In this way, the color difference of the light emitting devices may be improved and the surface haze effect may be improved by using the composite light scattering agent including the first filler 250 (first light scattering agent) and the second filler 251 (second light scattering agent).

The light scattering agent 250 and 251 may interfere with straightness of light emitted from a light source (light emitting device) constituting the unit pixel 211, 212, and 213, thereby causing light scattering, which is a kind of random reflection. Accordingly, the light scattering agent 250 and 251 may prevent a luminance deviation phenomenon in which light emitted from the unit pixel 211, 212, and 213 is biased in a specific direction.

In addition, the light scattering agent 250 and 251 may improve a phenomenon in which colors look different depending on the left and right positions and angles based on the position of the substrate 230 (e.g., a phenomenon in which the decrease in luminance is not uniform).

When the composite light scattering agent including the first filler 250 (first light scattering agent) and the second filler 251 (second light scattering agent) is used, a scattering effect may be increased, and a high content filler (light scattering agent) may be added.

For example, 10 to 20 wt % of Si oxide (SiO₂) to the weight of the base material such as silicon used as an example of the encapsulation layer 240 may have a scattering effect similar to 0.5 to 1 wt % of Zr oxide (ZrO₂). In addition, it may have a scattering effect similar to 0.001 to 0.005% of Ti oxide (TiO₂).

As described above, based on the scattering degree, since it is in the order of TiO₂>ZrO₂>SiO₂, using TiO₂ may be the most effective, but a turbidity phenomenon may occur due to TiO₂. Also, when a very small amount of scattering agent is used in the actual product application, a problem may occur due to a measurement error. Therefore, as suggested in the embodiment of the present disclosure, a plurality of scattering agents may be mixed and used. This will be described in detail later.

As described above, the unit pixel of the display panel 200 may be implemented by a light emitting device. In an embodiment of the present disclosure, a Light Emitting Diode (LED) is exemplified as a type of semiconductor light emitting device that converts current into light.

The substrate 230 may include glass or polyimide (PI). In order to implement a flexible display, the substrate 230 may be formed of any insulating and flexible material, for example, polyethylene naphthalate (PEN), polyethylene terephthalate (PET), or the like. Also, the substrate 230 may be formed of any one of a transparent material and an opaque material.

The substrate 230 may be a wiring substrate on which the electrode pad 220 and the wiring electrode (not shown separately) connected to the electrode pad 220 are disposed, and thus the electrode pad 220 may be located on the substrate 230.

The encapsulation layer 240 may be disposed on the substrate 230 where the electrode pad 220 is located. The encapsulation layer 240 is made of an insulating and flexible material such as polyimide (PI), PET, PEN, and the like, and may be integrally formed with the substrate 230 to form a single substrate.

Light emitting devices constituting each unit pixel 211, 212, and 213 may be connected to the electrode pad 220. Hereinafter, as an embodiment, a unit subpixel may have the same meaning as a light emitting device. Therefore, description will be made using the same reference numbers. For example, three subpixels may form one pixel. That is, the red (R) light emitting device 211, the green light emitting device 212, and the blue light emitting device 213 may form one pixel.

Each of the semiconductor light emitting devices 211, 212, and 213 constituting the unit pixel may be a micro LED having a size of several to hundreds of microns. In some cases, each of the semiconductor light emitting devices 211, 212, and 213 may be a mini LED having a size that is several tens of times larger than that of the micro LED. Here, the mini LED may have a stack structure different from that of the micro LED. Specifically, the mini LED may further include a growth substrate for growing a semiconductor layer.

As an example of the semiconductor light emitting devices 211, 212, and 213 constituting the unit pixel, the micro LEDs or mini LEDs may have a form in which red (R), green (G), and blue (B) LEDs independently emit light, as well as a stacked LED form consisting of red (R), green (G), and blue (B) layers on one LED.

A Thin Film Transistor (TFT) may be connected to the wiring electrode 241 to implement an Active Matrix (AM) type display device. As an example, the substrate 230 may be a TFT substrate. As another example, the substrate 230 may be a Passive Matrix (PM) type substrate.

In FIG. 1, a structure of the display panel 200 is simplified and illustrated briefly. Hereinafter, a detailed description of the configuration of the display panel 200 will be omitted.

As mentioned above, a composite optical film 100 may be positioned on the display panel 200.

The optical film 100 may include a black dye layer 101. The black dye layer 101 is a black dye having a preset transmittance, and may reduce a degree to which the transparent protective layer 101 is exposed to ultraviolet rays. For example, the black dye layer 101 may have a transmittance of 10% to 60%. In this case, the black dye layer 101 may include a UV blocking agent to increase a UV blocking effect. The black dye layer 101 may perform a function of increasing a contrast ratio.

Meanwhile, as described above, the light scattering agent 250 and 251 is a material having a relatively large refractive index and has an effect of improving a refractive index. The light scattering agent 250 and 251 having a large refractive index may exhibit a large scattering effect even when a small amount is added.

For example, the light scattering agent 250 and 251 may have an amorphous particle shape having an intermediate size of about 20 nm to about 1 μm. The light scattering agent 250 and 251 may be added to the encapsulation layer 240 by a dispensing process, and the light scattering agent 250 and 251 having a small size as described above may have stability with respect to the dispensing process. Also, it may have an advantage that a sedimentation phenomenon is less after a curing process through a dispensing process.

As an exemplary embodiment, the light scattering agent 250 and 251 may include Zr oxide (e.g., ZrO₂). Since the Zr oxide is a material having a high refractive index of 2.3, it may have a relatively large scattering effect.

As described above, Zr oxide has a refractive index greater than that of silicon oxide (SiO₂), thereby exhibiting a large scattering effect.

As in the first embodiment, when two or more kinds of light scattering agents 250 and 251 are mixed in the same layer (encapsulation layer 240) and used, both kinds of scattering agents 250 and 251 exhibit the effect of light scattering, or one light scattering agent (e.g., the second scattering agent 251) may be used for the purpose of preventing the sedimentation of the other major light scattering agent (e.g., the first scattering agent 250).

Based on light scattering data (unit: uW/cm2/nm) of the light scattering agent having the highest light scattering degree and constituting the encapsulation layer 240, the light scattering degree of the first light scattering agent 250 may be 0 to 100, and the light scattering degree of the second light scattering agent 251 may be 0 to 50.

In this way, when two or more kinds of light scattering agents 250 and 251 are used, a light scattering agent having a wide specific surface area may be used to prevent the sedimentation of the light scattering agent 250 and 251. In this case, when a spherical light scattering agent having a small specific surface area is used, a light scattering agent having a particle size (based on D50) of 10 μm or less may be used.

When the size of the light scattering agent is more than 10 μm, a phenomenon of sedimenting a plurality of light scattering agents sediment may occur, and the sedimented light scattering agent may cover an upper side of the light emitting device 210, resulting in luminance unevenness for each pixel position.

Here, regarding the meaning of D50 (intermediate value), since particle density distribution is important in the case of the particulate light scattering agent, the intermediate value is used instead of an average value. Since sizes of all particles have distribution, D50 may mean the size of the particle in the middle when sorting from the small to the large. For example, if there are 100 particles, D50 may mean the size of the particle corresponding to the 50^{th} order.

Meanwhile, in order to prevent a phenomenon in which the light scattering agent 250 and 251 is sedimented in the encapsulation layer 240 and fails to be evenly distributed in the encapsulation layer, a surface treatment may be performed on the light scattering agent. For example, a polar ionic bond or a functional group (—OH) may be coated on the surface of the light scattering agent. In addition, as another example, a flowability adjusting agent may be added to the surface of the light scattering agent. The flowability adjusting agent may be added in an amount of less than 10% based on the content of the light scattering agent. This may be to prevent an increase in thixotropy due to the influence of the flowability adjusting agent.

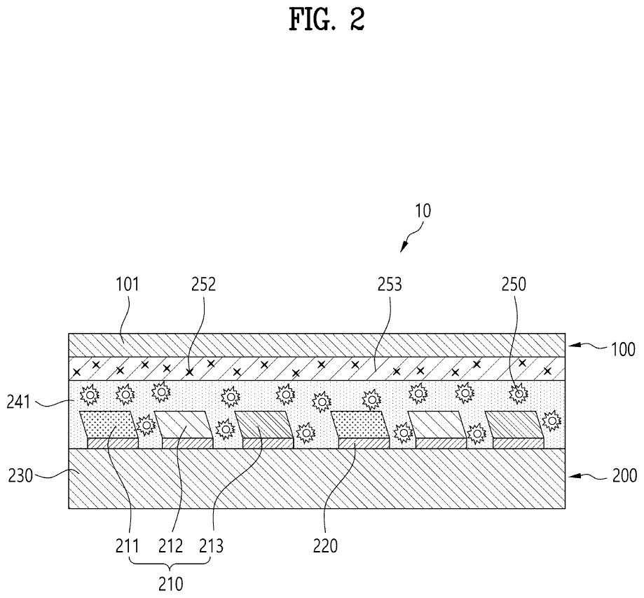

FIG. 2 is a schematic cross-sectional diagram illustrating a display device according to a second embodiment of the present disclosure.

As shown in FIG. 2, a display panel 200 may implement an image by a unit pixel 210 (211, 212, and 213) arranged on a substrate 230. Encapsulation layers 241 and 253 may be formed on the unit pixel 210 (211, 212, and 213).

The unit pixel 210 (211, 212, and 213) may include light emitting devices 211, 212, and 213. For example, the unit pixel 210 may include a red light emitting device 211, a green light emitting device 212, and a blue light emitting device 213.

The red light emitting device 211, the green light emitting device 212, and the blue light emitting device 213 constituting the unit pixel 210 may be electrically connected to an electrode pad 220 arranged on the substrate 230.

Meanwhile, unlike the illustration, the unit pixel 210 may include a stacked light emitting device (LED) in which red, green, and blue are formed in a single chip structure.

A composite optical film 100 may be positioned on the display panel 200. In this way, the composite optical film 100 may be attached onto the display panel 200. The display panel 200 to which the composite optical film 100 is attached may be referred to as a display device 10.

As an exemplary embodiment, the encapsulation layers 241 and 253 may include a first layer 241 covering a plurality of the light emitting devices 211, 212, and 213 and a second layer 253 positioned on the first layer 241.

Fillers 250 and 252 may be included in the encapsulation layers 241 and 253. The fillers 250 and 252 may include a first filler 250 and a second filler 252 having different optical characteristics from each other. Here, the optical characteristic may be a characteristic of refracting or scattering light emitted from the light emitting device 210.

Light emitted from the light emitting devices 211, 212, and 213 may be refracted or scattered by the fillers 250 and 252. Light scattered by the fillers 250 and 252 may be emitted to the outside of the encapsulation layers 241 and 253.

After the encapsulation layers 241 and 253 are cured, they may be transmissive. For example, the cured encapsulation layers 241 and 253 including silicon may have a refractive index of 1.4 to 1.6. Accordingly, light may be totally reflected in the encapsulation layers 241 and 253. The fillers 250 and 252 may refract or scatter light that is totally reflected in the encapsulation layers 241 and 253.

That is, the fillers 250 and 252 may serve as light scattering agents. Therefore, the fillers 250 and 252 may be referred to as light scattering agents. In the following description, the filler and the light scattering agent may refer to the same entity.

Referring to FIG. 2, the first filler 250 (first light scattering agent) may be included in the first layer 241, and the second filler 252 (second light scattering agent) may be included in the second layer 253.

As such, the first filler 250 and the second filler 252 may be included in different encapsulation layers 241 and 253, respectively.

As an embodiment, a scattering degree of the first light scattering agent 250 may be greater than a scattering degree of the second light scattering agent 252.

The fillers 250 and 252 may be characterized in including at least one of Zr, Si, Ti, Zn, BaS, and oxides thereof. For example, the fillers 250 and 252 may be spherical or amorphous. For example, the first filler 250 may be amorphous and the second filler 252 may be spherical.

As described above, for example, the first filler 250 may include Zr oxide. Also, for example, the second filler 252 may include Si oxide.

In this case, the optical characteristics of the first filler 250 may be different from the optical characteristics of the second filler 252. As mentioned above, the optical characteristics may be characteristics of refracting or scattering light emitted from the light emitting device 210.

Also, the characteristic of refracting or scattering the light emitted from the light emitting device 210 may be expressed as a scattering degree. A redundant description of the scattering degree is omitted.

As described above, according to an embodiment of the present disclosure, the color difference of the light emitting devices may be improved and the surface haze phenomenon may be improved, by using the composite light scattering agent including the first filler 250 (first light scattering agent) and the second filler 252 (second light scattering agent).

The light scattering agents 250 and 252 may interfere with straightness of light emitted from a light source (light emitting device) constituting the unit pixel 211, 212, and 213, thereby causing light scattering that is a kind of random reflection. Accordingly, the light scattering agents 250 and 252 may prevent a luminance deviation phenomenon in which light emitted from the unit pixel 211, 212, and 213 is biased in a specific direction.

In addition, the light scattering agents 250 and 252 may improve a phenomenon in which colors look different depending on the left and right positions and angles based on the position of the substrate 230 (e.g., a phenomenon in which the decrease in luminance is not uniform).

When the composite light scattering agent including the first filler 250 and the second filler 252 is used, a scattering effect may be increased, and a high content filler (light scattering agent) may be added.

The description of the first embodiment described above may be equally applied to other undescribed parts. Therefore, redundant descriptions are omitted.

In the case of the second embodiment, the first light scattering agent 250 included in the first layer 241 may be used to increase a light scattering effect on a chip side surface of the light emitting device 210. Therefore, in this case, a scattering degree of the first light scattering agent 250 may be higher than a scattering degree of the second light scattering agent 252.

As described above, the light scattering effect may be increased by using two light scattering agents 250 and 252 having different scattering degrees and particle sizes.

In the second embodiment, as the thickness of the encapsulation layer (resin layer) 241 increases, the encapsulation layer may be divided into a plurality of layers to include a light scattering agent in order to reduce the sedimentation phenomenon of the light scattering agent due to gravity.

In this case, the resin that forms the first layer 241 may be a resin capable of IR rapid curing or UV curing to prevent sedimentation.

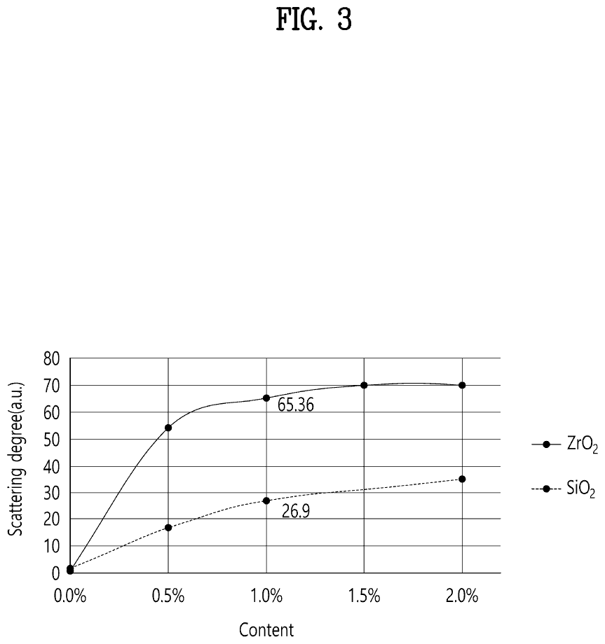

FIG. 3 is a graph illustrating characteristics of a light scattering agent used in a display device according to an embodiment of the present disclosure.

Referring to FIG. 3, scattering degrees of Zr oxide (ZrO₂) that may be used as the first filler 250 (the first light scattering agent) and Si oxide (SiO₂) that may be used as the second filler 251 or 252 (the second light scattering agent) described above are shown.

As described above, a characteristic of refracting or scattering light emitted from the light emitting device 210 may be expressed as a scattering degree.

The scattering degree shown in FIG. 3 may represent a result of measuring light intensity of scattered light, which is generated after irradiating the excitation light. Meanwhile, the scattering degree may be defined as the degree to which light emitted from the light emitting devices 211, 212, and 213 is scattered relative to a unit mass.

Referring to FIG. 3, when a light scattering agent is used at a weight ratio of 1% to an encapsulation layer, a scattering degree by Zr oxide (ZrO₂) may be two times or more greater than that of Si oxide (SiO₂).

That is, it may be said that the scattering degree of Zr oxide (ZrO₂) is superior to that of Si oxide (SiO₂) when the scattering degrees of the same content are compared. Therefore, when Zr oxide (ZrO₂) is used, a scattering effect may be increased even when a small content is used.

The scattering degrees of Si oxide (SiO₂) and Zr oxide (ZrO₂) are confirmed, and for example, a case in which Zr oxide (ZrO₂) is used at a weight ratio (1 wt %) in a size of 1 μm may be approximately equivalent to a case in which Si oxide (SiO₂) is used at a weight ratio (20 wt %) in a size of 5 μm.

When two or more of these light scattering agents are used together, it may bring an effect that luminance is improved by reducing the particle size applied to the encapsulation layer.

Additionally, when dispersing the light scattering agent in the encapsulation layer, there may be a tendency to sediment in a direction toward the substrate 230 due to the mass. When two or more light scattering agents are used together, the sizes and shapes of these particles may be changed to prevent the sedimentation of the light scattering agents.

Meanwhile, when two or more light scattering agents are used together, it is possible to change a refractive index through changes according to a combination of various types of scattering agents, and an overall content of the scattering agent may be reduced.

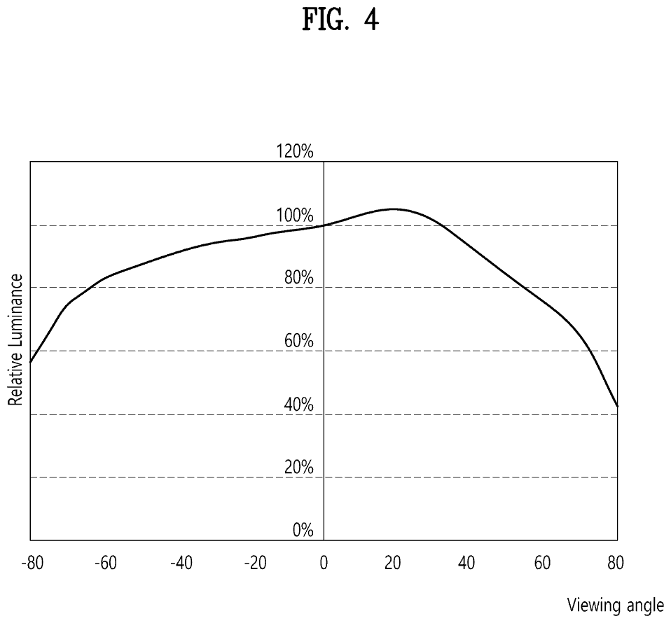

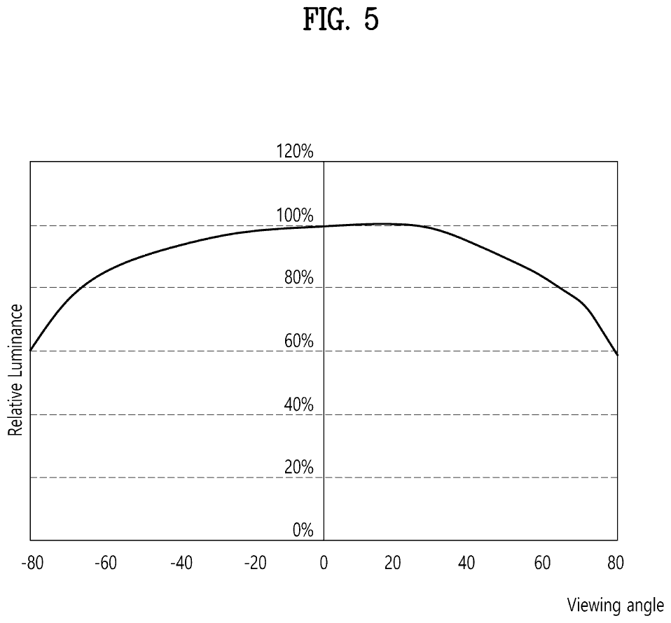

FIG. 4 is a graph showing a change in luminance according to a viewing angle of a display device in a state where a light scattering agent is not applied as a comparative example. Also, FIG. 5 is a graph showing a change in luminance per viewing angle of a display device according to an embodiment of the present disclosure.

Referring to FIG. 4, a distribution of luminance of white light according to a viewing angle is shown. When a light scattering agent is not applied, as shown in the drawing, it may be seen that the luminance distribution is skewed toward a positive angle with respect to 0°.

The light emitting device 210 usually has compound semiconductor crystals grown on a crystalline substrate such as sapphires, and such a light emitting device 210 has a chip tilt, as schematically shown in FIGS. 1 and 2.

The reason why the light emitting device 210 has the chip tilt may be due to properties of a crystal plane in a chip fabricating process. Typically, a substrate or a compound semiconductor crystal constituting the light emitting device 210 has an inclined crystal plane of a hexagonal lattice. Accordingly, in the process of cutting the light emitting devices 210 into individual chips after growth, the light emitting device 210 is cut depending on the crystal plane, and thus the individual light emitting device 210 is not cut in a perfect vertical direction. That is, a vertical cross section of the individual light emitting device 210 has the shape of a parallelogram rather than the shape of a rectangular parallelepiped.

Besides, the chip tilt of the light emitting device 210 may be attributed to tilt (slope) due to soldering or adhesion of the light emitting device 210. That is, when the light emitting device 210 is soldered or adhered to the electrode pad 220, the tilt due to non-uniformity of solder or adhesive may occur.

As a result, as shown in FIG. 4, the light emitted from the light emitting device 210 has a characteristic that a directional angle is not uniform and skewed with respect to the center of the light emitting device 210 chip.

In this case, when a light scattering agent is not applied, non-uniform distribution of light due to the chip tilt may be revealed as it is. As a result, a luminance deviation phenomenon in which the light emitted from the display panel 200 is biased in a specific direction may occur. As a result, a color difference may occur according to a viewing angle of the display device.

However, as shown in FIG. 5, according to an embodiment of the present disclosure, for example, when two or more light scattering agents are used together, it can be seen that it has a uniform luminance distribution at both positive and negative angles based on 0 degrees.

As described above, for example, a luminance deviation phenomenon of the display panel 200 may be prevented by an embodiment in which Zr oxide (ZrO₂) and Si oxide (SiO₂) are distributed in an encapsulation layer.

When the encapsulation layers 240 and 253 including the light scattering agents 250, 251, and 252 having the characteristics described above are located on the display panel 200, the uneven light distribution due to the chip tilt of the light emitting device 210 may become uniform.

Accordingly, a luminance deviation phenomenon in which light emitted from the display panel 200 is biased in a specific direction may be solved. As a result, a difference in color does not occur according to a viewing angle of the display device and a uniform color sense may be obtained.

As described above, a phenomenon in which colors feel different according to positions and angles based on the display panel 200 (reduction in luminance is not uniform) may be improved.

In addition, as described above, the light scattering agents 250, 251, and 252 are materials having a relatively large refractive index and have an effect of improving a refractive index. The light scattering agents 250, 251, and 252 having such a large refractive index may exhibit a large scattering effect even when a small amount is added.

For example, the light scattering agents 250, 251, and 252 may have an amorphous particle shape having an intermediate size of about 20 nm to about 1 μm. The light scattering agents 250, 251, and 252 may be added to the encapsulation layers 240 and 253 by a dispensing process. The light scattering agents 250, 251, and 252 having the small size as described above may have stability with respect to the dispensing process. Also, it may have an advantage that a sedimentation phenomenon is less after a curing process is performed after a dispensing process.

As an exemplary embodiment, the light scattering agents 250, 251, and 252 may include Zr oxide (e.g., ZrO₂). Since the Zr oxide is a material having a high refractive index of 2.3, it may have a relatively large scattering effect.

As described above, Zr oxide has a refractive index greater than that of silicon oxide (SiO₂), thereby exhibiting a large scattering effect.

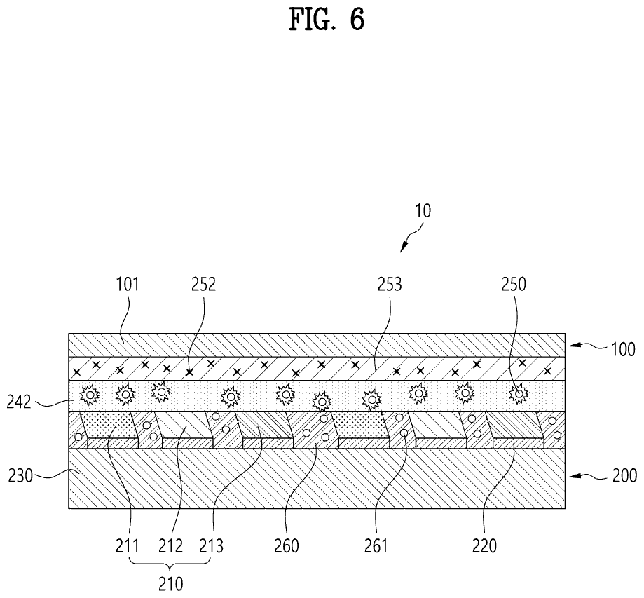

FIG. 6 is a schematic cross-sectional diagram illustrating a display device according to a third embodiment of the present disclosure.

As shown in FIG. 6, a display panel 200 may implement an image by unit pixels 210 (211, 212, and 213) arranged on a substrate 230. Encapsulation layers 242, 253, and 260 may be formed on the unit pixels 210 (211, 212, and 213).

The unit pixel 210 (211, 212, and 213) may include light emitting devices 211, 212, and 213. For example, the unit pixel 210 may include a red light emitting device 211, a green light emitting device 212, and a blue light emitting device 213.

The red light emitting device 211, the green light emitting device 212, and the blue light emitting device 213 constituting the unit pixel 210 may be electrically connected to an electrode pad 220 arranged on the substrate 230.

Meanwhile, unlike the illustration, the unit pixel 210 may include a stacked light emitting device (LED) in which red, green, and blue are formed in a single chip structure.

A composite optical film 100 may be positioned on the display panel 200. In this way, the composite optical film 100 may be attached onto the display panel 200. The display panel 200 to which the composite optical film 100 is attached may be referred to as a display device 10.

As an exemplary embodiment, the encapsulation layers 242, 253, and 260 may include a first layer 242 covering a plurality of the light emitting devices 211, 212, and 213 and a second layer 253 positioned on the first layer 242.

Also, the encapsulation layers 242, 253, and 260 may further include a third layer 260 positioned on the side surfaces of a plurality of the light emitting devices 211, 212, and 213. The third layer 260 may fill a top surface of the substrate 230 and the side surfaces of the light emitting devices 211, 212, and 213.

As described above, fillers 250 and 252 may be included in the first layer 242 and the second layer 253. The fillers 250 and 252 may include a first filler 250 and a second filler 252 having different optical characteristics from each other. Here, the optical characteristic may be a characteristic of refracting or scattering light emitted from the light emitting device 210.

Also, a third filler 261 may be included in the third layer 260. For example, the third layer 260 may include a third filler 261 having a scattering degree different from that of the first filler 250 or the second filler 252. That is, the third layer 260 may include a third light scattering agent 261 having a scattering degree different from that of the first light scattering agent 250 or the second light scattering agent 252.

As an embodiment, the scattering degree of the third light scattering agent 261 may be higher than the scattering degrees of the first light scattering agent 250 or the second light scattering agent 252.

Also, for example, a height of the third layer 260 may be equal to or less than that of the light emitting device 210. For example, a thickness of the third layer 260 may be 20 nm to 120 μm. This may be a thickness range considering a minimum size (10 nm) of the third light scattering agent 261 and a chip thickness of 80 μm to 100 μm of the light emitting device 210.

The fillers 250, 252, and 261 may include at least one of Zr, Si, Ti, Zn, BaS, and oxides thereof. For example, the fillers 250, 252, and 261 may be spherical or amorphous. For example, the first filler 250 may be amorphous and the second filler 252 may be spherical. Also, the third filler 261 may have a spherical shape.

Also, as described above, for example, the first filler 250 may include Zr oxide. Also, for example, the second filler 252 may include Si oxide. For example, the third light scattering agent 261 may include Ti oxide (TiO₂).

In this case, the optical characteristics of the first filler 250 may be different from the optical characteristics of the second filler 252. As mentioned above, the optical characteristics may be characteristics of refracting or scattering light emitted from the light emitting device 210.

Also, a characteristic of refracting or scattering light emitted from the light emitting device 210 may be expressed as a scattering degree. A redundant description of the scattering degree is omitted.

As such, according to an embodiment of the present disclosure, the color difference of the light emitting devices may be improved and the surface haze phenomenon may be improved by using the composite light scattering agent including the first filler 250, the second filler 252 and the third filler 261.

The light scattering agents 250, 252, and 261 may interfere with straightness of light emitted from a light source (light emitting device) constituting the unit pixel 211, 212, and 213, thereby causing light scattering that is a kind of random reflection. Accordingly, the light scattering agents 250, 252, and 261 may prevent a luminance deviation phenomenon in which light emitted from the unit pixel 211, 212, and 213 is biased in a specific direction.

In addition, the light scattering agents 250, 252, and 261 may improve a phenomenon in which colors look different depending on the left and right positions and angles based on the position of the substrate 230.

When the composite light scattering agent including the first filler (first light scattering agent) 250, the second filler (second light scattering agent) 252 and the third filler (third light scattering agent) 261 is used, a scattering effect may be increased and a high content filler (light scattering agent) may be added.

In general, when the same content is used, the effect of the light scattering agent is in the order of TiO₂, ZrO₂, and SiO₂.

In the case of TiO₂, the light scattering effect is the best, but it is advantageous to mix based on a very small amount (0.01 wt %) in order to exert a light scattering effect that does not affect the blackness of a product due to a strong whiteness phenomenon (a phenomenon that appears milky white). Therefore, the possibility of error in weight management and process application may be relatively high.

Therefore, as exemplified above, TiO₂, which has the highest light scattering effect, may be used as the third light scattering agent 261 in the third layer 260, ZrO₂ may be used in the first layer 242 that is an upper layer, and SiO₂ may be used in the second layer 253 that the uppermost layer.

In this way, the light scattering agent (the second light scattering agent 253) having the lowest light scattering degree may be located at the uppermost side. This may be because the higher the light scattering degree, the more blackness loss of the display may be affected. Accordingly, the uppermost configuration of the display may be composed of the content and material having the lowest light scattering degree.

Besides, the description of the first embodiment and the second embodiment described above may be equally applied to the parts not described. Therefore, redundant descriptions are omitted.

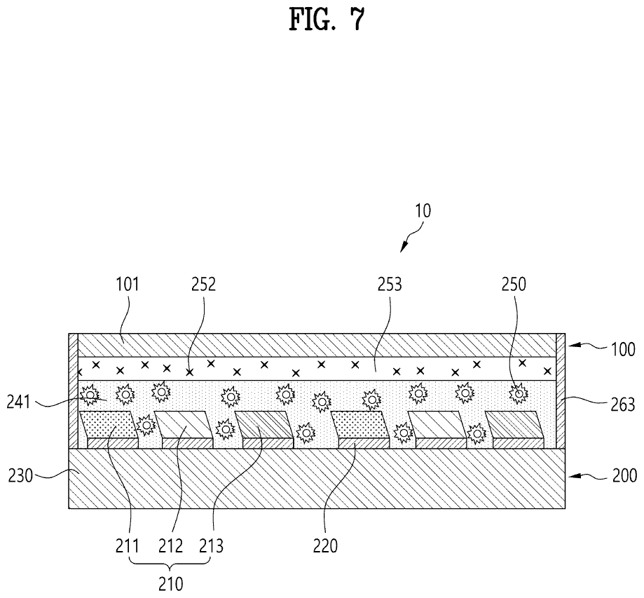

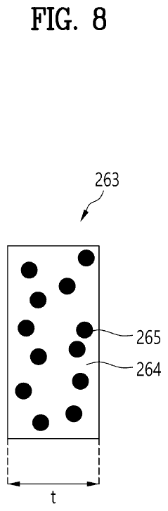

FIG. 7 is a schematic cross-sectional diagram illustrating a display device according to a fourth embodiment of the present disclosure. Also, FIG. 8 is an enlarged diagram illustrating a side optical layer of the display device according to the fourth embodiment of the present disclosure.

As shown in FIG. 7, a display panel 200 may implement an image by a unit pixel 210 (211, 212, and 213) arranged on a substrate 230. Encapsulation layers 241 and 253 may be formed on the unit pixel 210 (211, 212, and 213). The configuration of the encapsulation layers 241 and 253 may be the same as that of the second embodiment.

The unit pixel 210 (211, 212, and 213) may include light emitting devices 211, 212, and 213. For example, the unit pixel 210 may include a red light emitting device 211, a green light emitting device 212, and a blue light emitting device 213.

The red light emitting device 211, the green light emitting device 212, and the blue light emitting device 213 constituting the unit pixel 210 may be electrically connected to an electrode pad 220 arranged on the substrate 230.

Meanwhile, unlike the illustration, the unit pixel 210 may include a stacked light emitting device (LED) in which red, green, and blue are formed in a single chip structure.

A composite optical film 100 may be positioned on the display panel 200. In this way, the composite optical film 100 may be attached onto the display panel 200. The display panel 200 to which the composite optical film 100 is attached may be referred to as a display device 10.

As an exemplary embodiment, the encapsulation layers 241 and 253 may include a first layer 241 covering a plurality of the light emitting devices 211, 212, and 213 and a second layer 253 positioned on the first layer 241.

As described above, fillers 250 and 252 may be included in the first layer 241 and the second layer 253. The fillers 250 and 252 may include a first filler 250 and a second filler 252 having different optical characteristics from each other. Here, the optical characteristic may be a characteristic of refracting or scattering light emitted from the light emitting device 210.

In addition, the configurations of the encapsulation layers 241 and 253 and the fillers 250 and 252 may be the same as those of the second embodiment, so redundant descriptions are omitted.

Meanwhile, a side optical layer 263 may be positioned on side surfaces of the encapsulation layers 241 and 253 and the composite optical film 100 positioned on the substrate 230.

As mentioned above, a modular display device may be implemented in a manner that a plurality of display devices 10 are combined to implement a larger display area. For example, the display device 10 may be one display module constituting a modular display device. In this way, a plurality of the display devices 10 may be combined in parallel to form a modular display device. In this case, the side optical layer 263 may be located on an end portion side of each module display device 10.

As an exemplary embodiment, the side optical layer 263 may include a fourth filler (a fourth light scattering agent 265 (see FIG. 8)) having a scattering degree different from that of the first light scattering agent 250 or the second light scattering agent 252.

In this case, a scattering degree of the fourth light scattering agent 265 may be lower than the scattering degree of the first light scattering agent 250 or the second light scattering agent 252.

Referring to FIG. 8, the side optical layer 263 may be formed by dispersing the fourth light scattering agent 265 inside a resin layer 264. In this case, a thickness of the side optical layer 263 may be 20 nm to 50 μm.

It is advantageous that the light scattering degree of the fourth light scattering agent 265 included in the side optical layer 263 is less than 10% of the light scattering degree of the first light scattering agent 250 or the second light scattering agent 252.

The side optical layer 263 may prevent light emitted from the light emitting device 210 and scattered by the first light scattering agent 250 and the second light scattering agent 252 from overlapping or amplifying the scattered light emitted from an adjacent module display device.

In some cases, the fourth filler 265 included in the side optical layer 263 may be an absorbent instead of a light scattering agent.

Besides, the descriptions of the first to third embodiments may be equally applied to the parts not described.

The features, structures, and effects described in the embodiments above are included in at least one embodiment of the present invention and are not necessarily limited to a single embodiment. Furthermore, the features, structures, and effects exemplified in each embodiment can be combined or modified for other embodiments by those skilled in the art to which the embodiments pertain. Therefore, such combinations and modifications should be interpreted as being included within the scope of the present invention.

Although the embodiments have been described above for illustrative purposes, these are merely examples and are not intended to limit the present invention. Those skilled in the art to which the present invention pertains will understand that various modifications and applications not explicitly illustrated in the above examples are possible without departing from the essential characteristics of the present invention. For example, each component specifically described in the embodiments can be implemented with modifications. Differences related to such modifications and applications should be construed as being included within the scope of the present invention as defined by the appended claims.

### INDUSTRIAL APPLICABILITY

According to the present disclosure, it is possible to provide a display device capable of improving light uniformity by including a composite filler.

1. A display device, comprising:
a wiring substrate;
an electrode pad partitioned on the wiring substrate;
a plurality of light emitting devices connected to the electrode pad to form a unit pixel;
an encapsulation layer formed on the wiring substrate to cover the plurality of the light emitting devices;
an optical film disposed on the encapsulation layer; and
a light scattering agent dispersed and distributed in the encapsulation layer,
wherein the light scattering agent comprises a first light scattering agent and a second light scattering agent having a scattering degree different from a scattering degree of the first light scattering agent.

2. The display device of claim 1, wherein the light scattering agent comprises at least one of Zr, Si, Ti, Zn, BaS, and oxides thereof.

3. The display device of claim 1, wherein the encapsulation layer comprises:
a first layer covering the plurality of the light emitting devices; and
a second layer on the first layer.

4. The display device of claim 3, wherein the second light scattering agent is included in the second layer.

5. The display device of claim 3, wherein the scattering degree of the first light scattering agent is greater than the scattering degree of the second light scattering agent.

6. The display device of claim 1, wherein the encapsulation layer further comprises a third layer disposed on side surfaces of the plurality of the light emitting devices.

7. The display device of claim 6, wherein the third layer comprises: a third light scattering agent having a scattering degree different from the scattering degree of the first light scattering agent and the scattering degree of the second light scattering agent.

8. The display device of claim 7, wherein the scattering degree of the third light scattering agent is higher than the scattering degree of the first light scattering agent and the scattering degree of the second light scattering agent.

9. The display device of claim 6, wherein a height of the third layer is equal to or less than a height of the light emitting devices.

10. The display device of claim 1, further comprising a side optical layer disposed on a side surface of the encapsulation layer.

11. The display device of claim 10, wherein the side optical layer comprises: a fourth light scattering agent having a scattering degree different from the scattering degree of the first light scattering agent and the scattering degree of the second light scattering agent.

12. The display device of claim 1, wherein a diameter or size of the light scattering agent is 10 nm to 10 μm.

13. A display device, comprising:
a wiring substrate;
an electrode pad partitioned on the wiring substrate;
a plurality of light emitting devices connected to the electrode pad to form a unit pixel;
an encapsulation layer formed on the wiring substrate to cover the plurality of the light emitting devices;
an optical film disposed on the encapsulation layer; and
a filler dispersed and distributed in the encapsulation layer,
wherein the filler comprises a first filler including Zr oxide and a second filler including Si oxide.

14. The display device of claim 13, wherein the encapsulation layer comprises:
a first layer covering the plurality of the light emitting devices; and
a second layer on the first layer.

15. The display device of claim 14, wherein the second filler is included in the second layer.

16. The display device of claim 13, wherein the encapsulation layer further comprises a third layer disposed on side surfaces of the plurality of the light emitting devices.

17. The display device of claim 16, wherein the third layer comprises: a third filler having optical characteristics different from optical characteristics of the first filler and the second filler.

18. The display device of claim 17, wherein the third filler comprises Ti oxide.

19. The display device of claim 17, wherein a scattering degree of the third filler is higher than a scattering degree of the first filler and the second filler.

20. The display device of claim 13, further comprising a side optical layer disposed on a side surface of the encapsulation layer,
wherein the side optical layer comprises: a fourth filler having a scattering degree different from a scattering degree of the first filler and the second filler.
